(19) United States
(12) Patent Application Publication
(10) Pub. No.: US 2011/0017295 A1
(43) Pub. Date: Jan. 27, 2011

(54) PACKAGE FOR SOLAR CELL CHIP

(75) Inventors: TAI-CHERNG YU, Tu-Cheng (TW); YUNG-LUN HUANG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/842,047

(22) Filed: Jul. 23, 2010

(30) Foreign Application Priority Data
Jul. 24, 2009 (CN) 200910304824.7

(51) Int. Cl. H01L 31/0203

(52) U.S. Cl. 136/259

(57) ABSTRACT

A solar cell package comprises a substrate, a light-electricity transformation unit provided on the substrate for transforming solar energy into electricity, a package component covering the light-electricity transformation unit and the substrate, and a carbon nanotube film. The carbon nanotube film is provided on a surface of the light-electricity transformation unit to increase heat dissipation. A Fresnel lens is disposed corresponding to the top of the light-electricity transformation unit, and converges and concentrates solar energy on the light-electricity transformation unit.

### BACKGROUND

1. Technical Field

The present application is related to a solar cell device, and especially to a package of a solar cell chip.

2. Description of Related Art

Nowadays, with the resources on the earth being depleted day by day, the cost of investment for energy increases significantly. Solar energy has drawn attention from the energy industry as an alternative source of energy, and found widespread applications in a variety of fields.

Solar cells are usually packed and realized as semiconductor devices. During operation of such semiconductor devices, temperature of semiconductor devices increases due to heat created by solar cells. Therefore, operation efficiency of the semiconductor devices for solar cells will decrease.

A solar cell is conventionally integrated on a substrate, and a metal plate is soldered on the substrate for dissipating heat created by the solar cell. However, the heat dissipation plate is costly, and does not provide efficient dissipation.

### BRIEF DESCRIPTION OF THE DRAWINGS

The figure is an illustration of the embodiment of the present application.

### DETAILED DESCRIPTION

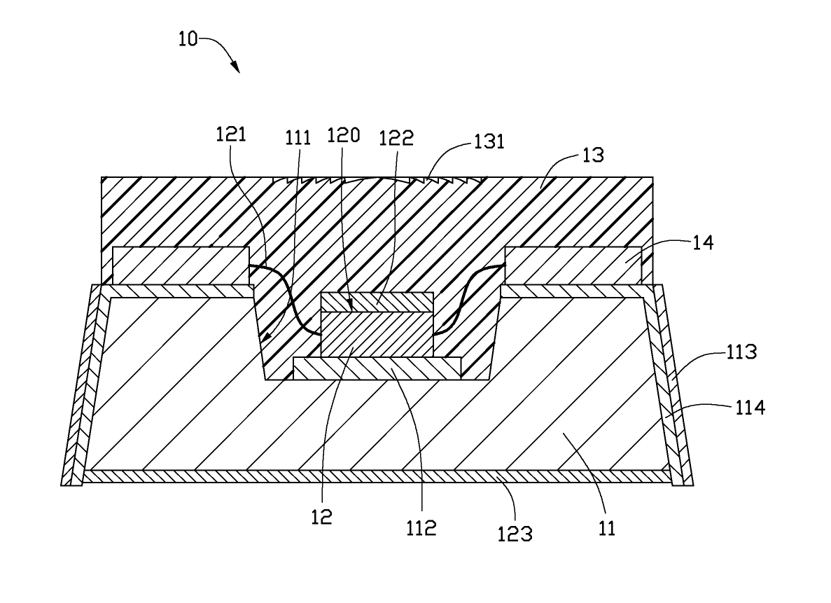

Referring to FIG. 1, a solar cell package 10 comprises a substrate 11, a plurality of light-electricity transformation units 12, a package component 13, and a circuit unit 14. The substrate 11 can be made of aluminum or ceramics. In one example, the light-electricity transformation unit 12 can be embodied as a non-silicon based solar cell chip, a silicon based solar cell chip, or a solar cell chip made of group III-V compounds. The group III-V compounds can be Gallium nitride (GaN), Gallium arsenide (GaAs), Gallium antimonide (GaSb), or Indium phosphide (InP).

The light-electricity transformation unit 12 is electrically connected to a circuit unit 14 through a carbon nanotube line 121 with high transmittance. The light-electricity transformation unit 12 is positioned on the substrate 11 by an adhesive layer 112 to receive sunlight and transform sunlight into electricity. The carbon nanotube line 121 could be single-walled or multi-walled nanotubes. The substrate 11 comprises a cavity 111 configured to receive the light-electricity transformation unit 12.

In one exemplary non-limiting embodiment, the light-electricity transformation unit 12 could be several small chips arranged in a matrix sized within 1 square millimeters (mm²) to 9 mm², or an isolated chip. A first carbon nanotube film 122 is provided on the light-electricity transformation unit 12 to increase heat dissipation. The first carbon nanotube film 122 could be constituted by single-walled carbon nanotubes, multi-walled nanotubes, or combination of the both.

The light-electricity transformation unit 12 transforms light into electricity. The circuit unit 14 is positioned on the ceramic substrate 11 by the adhesive layer 112, and is electrically connected to the light-electricity transformation units 12 for outputting electricity.

Material of the package component 13 can be selected from the group consisting of: polydimethylsiloxane (PDMS), polyepoxide (epoxy), and polymethyl methacrylate (PMMA). The package component 13 covers the substrate 11 and the light-electricity transformation unit 12, and a Fresnel lens 131 is formed on a position on the package component 13 corresponding to the position of the light-electricity transformation unit 12. The package component 13 prevents moisture from penetrating to the light-electricity transformation unit 12 and the circuit unit 14 on the substrate 11 causing short circuits, like water drops.

The size of the Fresnel lens 131 can correspond to the size of the light-electricity transformation unit 12, and the numbers of the Fresnel lens 131 can correspond to the numbers of the light-electricity transformation unit 12. The inclusion of Fresnel lens 131 causes the incident angle of light therethrough to be relatively smaller. Therefore, the Fresnel lens 131 concentrates light onto the light-transformation unit 12 and reduces energy loss.

A metal layer 113 is provided on a lateral surface of the substrate 11 to reduce electromagnetic interference. An insulation layer 114 is provided between the metal layer 113 and the substrate 11 to prevent rusting.

A second carbon nanotube film 123 is provided on a surface opposite to the surface carrying the light-electricity transformation unit 12, to increase heat dissipation of the light-electricity transformation unit 12. The second carbon nanotube film 123 can be constituted of single-walled nanotubes, multi-walled nanotubes, or combination of the both.

While the disclosure has been described by way of example and in terms of preferred embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell chip module, comprising:
a substrate;
a light-electricity transformation unit provided on the substrate to transform light energy into electricity;
a first carbon nanotube film positioned on the light-electricity transformation unit;
a package component covering the first carbon nanotube film and the light-electricity transformation unit to prevent damage.

2. The solar cell chip module as claimed in claim 1, wherein the carbon nanotube film is constituted by single-walled carbon nanotubes or multi-walled carbon nanotubes.

3. The solar cell chip module as claimed in claim 1, further comprising a circuit unit provided on the substrate, wherein the light-electricity transformation unit is electrically connected to the circuit unit through carbon nanotubes.

4. The solar cell chip module as claimed in claim 4, wherein the carbon nanotubes are single-walled nanotubes or multi-walled nanotubes.

5. The solar cell chip module as claimed in claim 1, wherein a second carbon nanotube film is provided on a surface of the substrate which is opposite to the surface carrying the light-electricity transformation unit, to dissipate heat.

6. The solar cell chip module as claimed in claim 1, wherein a metal layer is provided on a lateral surface of the substrate to reduce electromagnetic interference.

7. The solar cell chip module as claimed in claim 7, wherein the metal layer is made of copper or stainless steel.

8. The solar cell chip module as claimed in claim 7, wherein an insulation layer is formed between the metal layer and the substrate to prevent from rust.

9. The solar cell chip module as claimed in claim 1, wherein the solar cell chip is fastened on the substrate by adhesive.
